(19) United States
(12) Patent Application Publication
(10) Pub. No.: US 2003/0058678 A1
(43) Pub. Date: Mar. 27, 2003

(54) Ferroelectric memory device and method of fabricating the same

(76) Inventors: Hyoung-Joon Kim, Seoul (KR); Yong-Tak Lee, Yongin-shi (KR)

Correspondence Address: HARNESS, DICKEY & PIERCE, P.L.C., P.O. BOX 8910, RESTON, VA, 20195, US

(21) Appl. No.: 10/193,901

(22) Filed: Jul. 15, 2002

(30) Foreign Application Priority Data
Sep. 27, 2001 (KR) 2001-59956

(51) Int. Cl. G11C 17/00

(52) U.S. Cl. 365/100; 257/295

(57) ABSTRACT

In the ferroelectric memory device an auxiliary polysilicon layer is formed on an interlayer insulating layer having a polysilicon contact plug formed therein. A metal silicide layer is formed on the auxiliary polysilicon layer. A capacitor structure is then formed on the metal silicide layer.

This application relies for priority upon Korean Patent Application No. 2001-59956, filed on Sep. 27, 2001, the contents of which are herein incorporated by reference in their entirety.

### FIELD OF THE INVENTION

The present invention relates to a ferroelectric memory device (FRAM) and a method of fabricating the same.

### BACKGROUND OF THE INVENTION

A ferroelectric material exhibits polarization when an external electric field is applied, and maintains the polarization even after removing the external electric field. Also, the ferroelectric material is a material that makes it possible to control a direction of spontaneous polarization according to a change of the electric field. The ferroelectric material typically includes PZT[Pb(Zr, Ti)O₃], SBT[SrBi₂Ta₂O₉] and the like. The characteristics of the ferroelectric material may be used for forming binary memory devices. Thus, extensive studies have been made of a ferroelectric memory device such as a ferroelectric random access memory (FRAM). In order to form the ferroelectric memory device, materials such as PZT, SBT should have a perovskite structure. The method of forming the perovskite structure comprises stacking the materials such as PZT, SBT in an amorphous state and then annealing them at an oxidizing ambient of a high temperature, e.g., 700° C., to be crystallized.

When forming a capacitor of a FRAM, a lower electrode of the capacitor is connected to a conductive region of a substrate by a contact plug. Generally, an interlayer insulating layer covers the substrate and a conductive layer is formed over the substrate to fill a contact hole in the interlayer insulating layer exposing the substrate. Thereafter, the conductive layer is etched to expose a top surface of the interlayer insulating layer. As a result, the contact plug is formed. In this case, the conductive layer is typically composed of polysilicon or the like. Also, the lower and/or upper electrode of the capacitor is typically composed of a noble metal, which is resistant to annealing in an oxygen ambient.

When the lower electrode of a ferroelectric capacitor is formed in contact with a top surface of a polysilicon contact plug, a Shottky barrier is formed between the metal constituting the lower electrode and the polysilicon constituting the contact plug. In some lower electrodes, e.g., a platinum lower electrode, oxygen may diffuse into the top surface of the contact plug to form a silicon oxide layer, which is an insulator. As a result, an interface resistance between the lower electrode and the contact plug increases, and the increased interface resistance may deteriorate or stop operation of a device.

To minimize the contact interface resistance, a metal silicide may be formed between the polysilicon layer constituting the contact plug and the noble metal constituting the lower electrode. The metal silicide layer forms a good ohmic contact at the interface between the contact plug and the lower electrode. To form the metal silicide layer, a metal layer is formed over the substrate having the contact plug and interlayer insulating layer formed thereon. The substrate having the metal layer is annealed to form the metal silicide. The unsilicided metal layer is then removed from an interlayer insulating layer. A capacitor is formed on top of the silicided contact plug. The capacitor includes a metal lower electrode, a ferroelectric layer and an upper electrode.

However, in the prior art, even if the metal silicide layer is formed at the interface between the lower electrode and the contact plug, the contact hole may not be completely filled with polysilicon. Thus, there may arise disadvantages such as a seam or a void.

FIGS. 1 through 4 are cross-sectional views showing these conventional problems. Referring to FIG. 1, a lower structure is formed on a substrate. For example, a gate insulating layer and a gate layer are stacked and patterned on a substrate 10, having a device isolation layer 11, to form a gate pattern 13. Thereafter, ion implantation is performed using the gate pattern 13 as an ion implantation mask to form a transistor. In this case, a contact pad for a lower electrode of a capacitor, and a bit line contact pad may be formed in a conductive region of the transistor. A first interlayer insulating layer 15 is stacked and patterned on the substrate 10, where the transistor is formed, to form a bit line contact hole. A conductive layer is stacked and patterned on the substrate where the bit line contact hole is formed, to form a bit line contact plug 17 and a bit line 19. A second interlayer insulating layer 21 is stacked on the bit line 19, and patterned to form a lower electrode contact hole 23 of the capacitor. Since the bit line 19 and the bit line contact plug 17 are not in the cross-section including the lower electrode contact hole 23 of the capacitor, they have been illustrated as dotted lines.

Referring to FIG. 2, polysilicon is stacked by chemical vapor deposition (CVD) on the substrate 10 where the lower electrode contact hole 23 is formed. Thereafter, a planarizing etch is performed by chemical mechanical polishing (CMP) to expose the second interlayer insulating layer 21 so that a contact plug 25 is formed. If the polysilicon layer is not formed to a sufficient thickness, or the contact hole is not completely filled with the polysilicon, a seam 27 or a void may be formed. The seam 27 or the void is not removed by the planarizing etch of the polysilicon layer and still remains in the contact plug 25.

Referring to FIG. 3, a metal selected from the group consisting of tungsten, cobalt, and titanium is stacked by sputtering or the like over the substrate where the contact plug 25 is formed. At this time, the void or the seam 27 is covered with the metal layer and not exposed. Continuously, by annealing, the metal layer reacts on an upper portion 251 of the polysilicon layer constituting the contact plug 25 to form a metal suicide 29. The metal silicide 29 is formed only on top 251 of the contact plug 25 because there is no silicon layer for the metal to react with other than at the contact plug region. However, metal in a region including the seam 27 is not silicided. Accordingly, if the non-reacted metal is removed by an etching process with selectivity between the metal silicide and the metal, the seam 27 in the contact plug 25 is exposed again.

Referring to FIG. 4, an adhesive layer, a lower electrode layer, a ferroelectric layer and an upper electrode are stacked on the seam 27. By patterning the foregoing layers, a ferroelectric capacitor that includes an adhesive pattern 311, a lower electrode 331, a ferroelectric layer pattern 351 and an upper electrode 371 is formed. Because of the seam 27, the contact area between the lower electrode 331 and the contact plug 25 is reduced. Thus, the contact interface resistance is increased. If, during subsequent processing, a ferroelectric layer is annealed in an oxidizing ambient to exhibit ferroelectric characteristics, the polysilicon constituting the contact plug 25 may diffuse through the void or the seam. Thus, silicon protrudes from the contact hole penetrating the thin adhesive layer pattern 311. The protruded silicon is oxidized at an oxidizing ambient of a high temperature and interposed between the lower electrode 331 and the contact plug 25. Therefore, the interface resistance between the lower electrode 331 and the contact plug 25 increases.

In addition, when the metal silicide 29 is formed on the top 251 of the contact plug 25, thermal stress becomes worse among the interlayer insulating layer 21, the contact plug 25, and the metal silicide 29 of a top surface 251 of the contact plug 25 during the annealing for forming the metal silicide 29 or during a subsequent annealing process. Because of such thermal stress, the interlayer insulating layer 21 or the metal silicide 29 may be broken or stripped. Consequently, the ferroelectric memory may suffer from a deterioration of operation characteristics.

### SUMMARY OF THE INVENTION

In the ferroelectric memory device according to the present invention, an auxiliary conductive layer is formed over the substrate and on the interlayer insulation layer and the contact plug formed in the interlayer insulation layer. A metal silicide layer is then formed on the auxiliary conductive layer. The auxiliary conductive layer minimizes the detrimental affects a void or seam in the contact plug has on the interface resistance between the contact plug and a subsequently formed lower electrode of capacitor formed over the contact plug. In addition, the auxiliary conductive layer helps prevent structural damage caused by thermal stress when the metal silicide layer is formed.

### BRIEF DESCRIPTION OF THE DRAWINGS

FIGS. 1 through 4 are cross-sectional views showing conventional problems when forming metal silicide on a contact plug.

FIGS. 5 through 7 are cross-sectional views showing characteristic steps in a method of forming a COB-type FRAM capacitor in accordance with the present invention.

### DESCRIPTION OF THE PREFERRED EMBODIMENT

The present invention will now be described more fully hereinafter with reference to the accompanying drawings, in which preferred embodiments of the invention are shown.

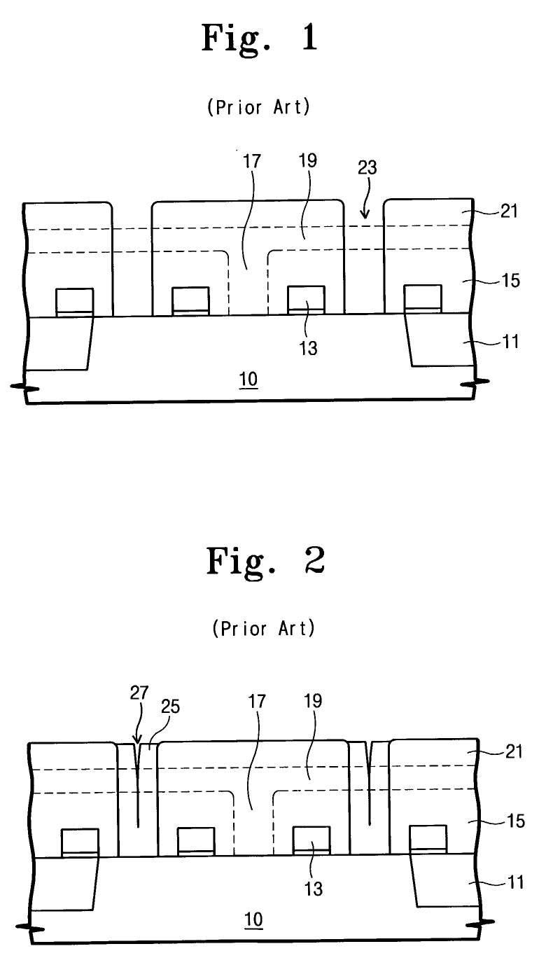

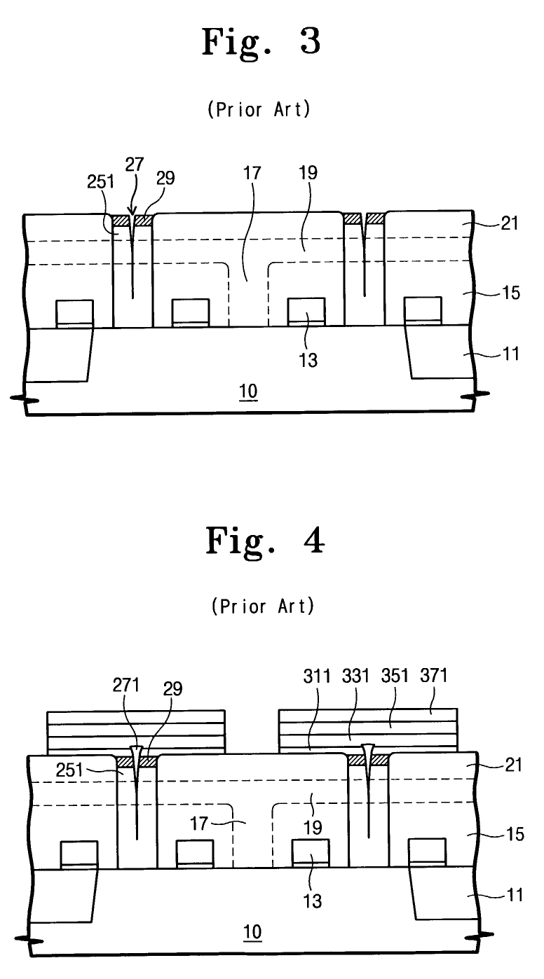

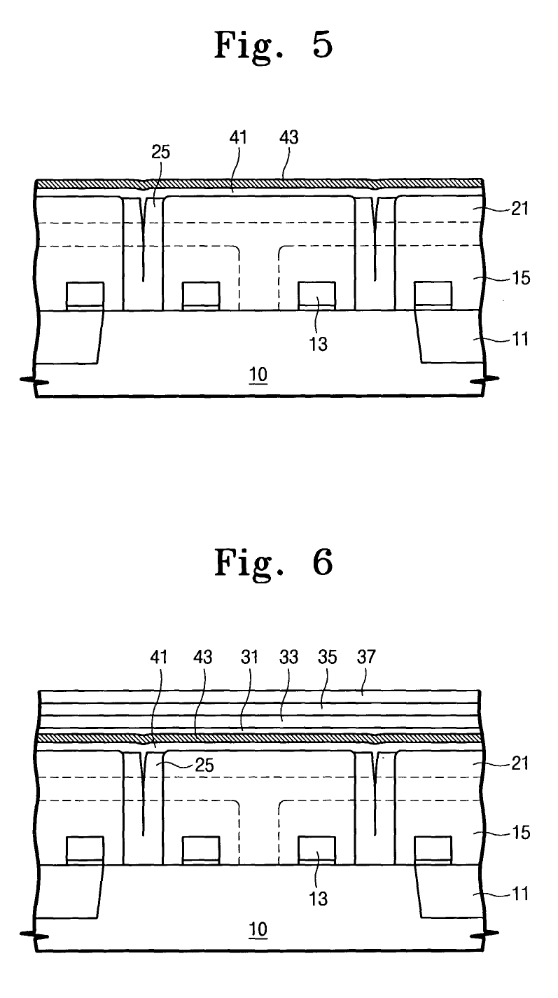

In FIG. 5, after the prior art method of forming the polysilicon contact plug 25 in a contact hole of the interlayer insulating layer 21 as described with respect to FIGS. 1 and 2, an auxiliary polysilicon layer 41 is stacked on the interlayer insulating layer 21 and the contact plug 25. A metal silicide layer 43 is then formed on the auxiliary polysilicon layer 41. In the foregoing steps, the auxiliary polysilicon layer 41 is stacked to fill a void or a seam exposed during a planarizing etch for forming the contact plug 25. That is, the void or the seam is covered while stacking the auxiliary polysilicon layer 41 on the interlayer insulating layer 21 and the contact plug 25. Therefore, a metal such as titanium, cobalt, and tungsten is stacked on a surface of the auxiliary polysilicon layer 41, and then annealed to form the metal silicide layer 43 on an entire surface of the auxiliary polysilicon layer 41. Consequently, a portion unsilicided due to the void or the seam does not exist on the surface of the auxiliary polysilicon layer 41.

In FIG. 6, an oxygen barrier layer 31, a lower electrode layer 33, a ferroelectric layer 35, and an upper electrode layer 37 are sequentially stacked on the metal silicide layer 43 formed in FIG. 5. The oxygen barrier layer 31 such as titanium, titanium aluminum nitride, titanium nitride and the like, may be omitted when the lower electrode layer 33 is composed of a metal such as iridium having an oxygen barrier characteristic. Regardless of the omission of the oxygen barrier layer 31, an adhesive layer such as a titanium layer may be additionally formed for improving adhesion between the metal silicide layer 43 and the lower metal layer 33.

The lower and upper electrode layers 33 and 37 may be composed of at least one selected from the group consisting of noble metals and their conductive oxides. The noble metals include platinum, iridium, ruthenium, osmium and the like. In addition, a ferroelectric material is stacked over the substrate on the lower electrode layer 33 by sputtering or a sol-gel doping process to form the ferroelectric layer 35. The ferroelectric material includes PZT [Pb(ZR, Ti)O₃], SrTiO₃, BaTiO₃, BST(Ba,Sr)TiO₃], SBT(SrBi₂Ta₂O₉), (Pb,La)(Zr,Ti)O₃, Bi₄Ti₃O₁₂ and the like. Thereafter, the substrate 10, where the ferroelectric material is stacked, is annealed at an oxidizing ambient of a high temperature of about 700° C.

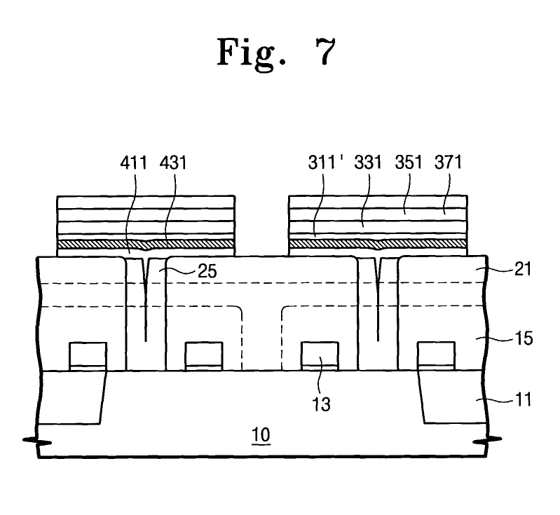

Referring to FIG. 7, an etch mask is formed on the resultant structure of FIG. 6. Then, the upper electrode layer 37, the ferroelectric layer 35, and the lower electrode layer 33 are sequentially etched to be patterned. As a result, a capacitor that includes a lower electrode 331, a ferroelectric pattern 351, and an upper electrode 371 is formed. By a subsequent etching process, an oxygen barrier layer pattern 311′, a metal silicide layer pattern 431 and an auxiliary polysilicon layer pattern 411 are formed, and the interlayer insulating layer 21 is exposed. Thereafter, in general, the ferroelectric pattern 351 is additionally annealed for curing etching damages.

As shown in FIG. 7, a seam or a void may be removed by the stacking of an auxiliary polysilicon layer 41 according to the present invention. Also, even if the void or seam remains in a contact plug 25, the void or the seam may be covered with the auxiliary polysilicon layer 41 and the metal silicide layer 43. Consequently, the seam does not come in contact with other material layers, e.g., an oxygen barrier layer 31, while the ferroelectric layer 35 is stacked, annealed or patterned, and then annealed for curing etching damages. Likewise, silicon does not diffuse through a void. That is, silicon may be prevented from penetrating the oxygen barrier layer 31. Thus, forming an insulated layer such as a silicon oxide layer on top of the contact plug is avoided.

When an edge of the auxiliary polysilicon layer 41 is exposed by patterning to form the capacitor, the edge may be oxidized when the ferroelectric pattern 351 is annealed to cure etching damage. However, since the oxygen barrier layer pattern 311′ minimizes oxygen inflow into an upper portion of the auxiliary polysilicon layer pattern 411, most of the auxiliary polysilicon layer pattern 411 between a lower electrode 331 and the contact plug 25 remains conductive polysilicon. That is, a resistance between the lower electrode 331 and the contact plug 25 is minimized.

The present invention prevents the detrimental affects of a seam or void formed in a top of a contact plug of a capacitor during formation of a COB-type FRAM capacitor. As a result, an increase in the resistance between the contact plug and the lower electrode because of the seam or the void is avoided.

The invention being thus described, it will be obvious that the same may be varied in many ways. Such variations are not to be regarded as a departure from the spirit and scope of the invention, and all such modifications are intended to be included within the scope of the following claims.

What is claimed is:

1. A ferroelectric memory device, comprising:
a substrate;
an interlayer insulating layer formed on the substrate;
a polysilicon contact plug filling a contact hole in the interlayer insulating layer;
an auxiliary polysilicon layer pattern formed on the contact plug and the interlayer insulating layer to cover the contact plug;
a metal silicide layer pattern formed on the auxiliary polysilicon layer pattern; and
a capacitor formed on the metal silicide layer pattern, the capacitor having a lower electrode, a ferroelectric pattern and an upper electrode.

2. The ferroelectric memory device of claim 1, wherein a conductive oxygen barrier pattern is interposed between the auxiliary polysilicon layer pattern and the lower electrode.

3. The ferroelectric memory device of claim 1, wherein an adhesive layer pattern is interposed between the auxiliary polysilicon layer pattern and the lower electrode.

4. The ferroelectric memory device of claim 1, wherein sidewalls of the auxiliary polysilicon layer pattern, the metal silicide layer pattern, the lower electrode, the ferroelectric pattern and the upper electrode are aligned.

5. The ferroelectric memory device of claim 1, wherein the metal silicide layer pattern is formed by using a metal selected from the group consisting of tungsten cobalt, and titanium.

6. The ferroelectric memory device of claim 1, wherein an oxygen barrier layer pattern is formed between the metal suicide layer pattern and the lower electrode, and the oxygen barrier layer pattern is composed of one selected from the group consisting of titanium, titanium aluminum nitride, and titanium nitride.

7. A ferroelectric memory device, comprising:
an auxiliary conductive layer formed over a substrate and on a contact plug, the auxiliary conductive layer and the contact plug being of a same material.

8. The ferroelectric memory device of claim 7, wherein the auxiliary conductive layer and the contact plug are polysilicon.

9. A ferroelectric memory device, comprising:
an auxiliary conductive pattern formed over a substrate and on a contact plug; and
a metal silicide layer pattern formed on the auxiliary conductive pattern.

10. The ferroelectric memory device of claim 9, wherein the auxiliary conductive pattern and the contact plug are formed of polysilicon.

11. The ferroelectric memory device of claim 9, further comprising:
a capacitor formed on the metal suicide layer pattern, the capacitor having a lower electrode, a ferroelectric pattern and an upper electrode.

12. The ferroelectric memory device of claim 11, wherein a conductive oxygen barrier pattern is interposed between the auxiliary conductive pattern and the lower electrode.

13. The ferroelectric memory device of claim 11, wherein an adhesive layer pattern is interposed between the auxiliary conductive pattern and the lower electrode.

14. The ferroelectric memory device of claim 11, wherein sidewalls of the auxiliary conductive pattern, the metal silicide layer pattern, the lower electrode, the ferroelectric pattern and the upper electrode are aligned.

15. The ferroelectric memory device of claim 9, wherein the contact plug is formed in an interlayer insulating layer, which is formed over the substrate.

16. A method of fabricating a ferroelectric memory device, comprising:
forming an interlayer insulating layer on a substrate;
forming a contact hole in the interlayer insulating layer;
forming a polysilicon layer over the substrate and substantially filling the contact hole;
performing a planarizing etch with respect to the polysilicon layer to expose the interlayer insulating layer so that a polysilicon contact plug is formed in the contact hole;
forming an auxiliary polysilicon layer on the polysilicon contact plug and the interlayer insulating layer;
forming a metal silicide layer on the auxiliary polysilicon layer; and
forming a lower electrode layer over the metal silicide layer.

17. The method of claim 16, further comprising:
forming an oxygen barrier layer on the metal silicide layer.

18. The method of claim 16, further comprising:
forming an adhesive layer on the metal silicide layer.

19. The method of claim 16, wherein the step of forming the metal silicide layer comprises:
forming a metal layer on the auxiliary polysilicon layer; and
annealing the metal layer and the auxiliary polysilicon layer.

20. The method of claim 16, further comprising:
sequentially forming a ferroelectric layer and an upper electrode layer on the lower electrode layer;
forming an etch mask on the upper electrode layer;
sequentially etching the upper electrode layer, the ferroelectric layer, and the lower electrode layer using the etch mask to form a capacitor; and
annealing to cure etching damages to the ferroelectric layer.

21. The method of claim 20, further comprising:
etching the metal silicide layer and the auxiliary polysilicon layer using the etch mask.

22. A method of fabricating a ferroelectric memory device, comprising:
forming an auxiliary conductive layer over a substrate and on a contact plug, the auxiliary conductive layer and the contact plug being of a same material.

23. The method of claim 22, wherein the auxiliary conductive layer and the contact plug are polysilicon.

24. A method of fabricating a ferroelectric memory device, comprising:
forming an auxiliary conductive layer over a substrate and on a contact plug; and
forming a metal silicide layer on the auxiliary conductive layer.

25. The method of claim 24, wherein the auxiliary conductive layer and the contact plug are formed of polysilicon.

26. The method of claim 24, further comprising:
forming a capacitor over the metal silicide layer, the capacitor having a lower electrode layer, a ferroelectric layer and an upper electrode layer.

27. The method of claim 26, further comprising:
forming a conductive oxygen barrier layer on the auxiliary conductive layer.

28. The method of claim 26, further comprising:
forming an adhesive layer on the auxiliary conductive layer.

29. The method of claim 26, wherein the forming a capacitor includes etching the lower electrode layer, the ferroelectric layer, the upper electrode layer, the metal silicide layer and the auxiliary conductive layer so that sidewalls of the auxiliary conductive layer, the metal silicide layer, the lower electrode layer, the ferroelectric layer and the upper electrode layer are aligned.

30. The method of claim 24, wherein the contact plug is formed in an interlayer insulating layer, which is formed over the substrate.
